(19) United States
(12) Patent Application Publication
(10) Pub. No.: US 2026/0251714 A1
(43) Pub. Date: Aug. 27, 2026

(54) STATE DETECTION DEVICE OF SWITCH CIRCUIT

(71) Applicant: TOYO DENSO KABUSHIKI KAISHA, Tokyo (JP)

(72) Inventors: Haoyang Qu, Shanghai (CN); Tsurugi Kojima, Tsurugashima-shi (JP); Shinya Inaba, Tsurugashima-shi (JP); Takeshi Uda, Tsurugashima-shi (JP)

(73) Assignee: TOYO DENSO KABUSHIKI KAISHA, Tokyo (JP)

(21) Appl. No.: 19/546,574

(22) Filed: Feb. 23, 2026

(30) Foreign Application Priority Data
Feb. 26, 2025 (CN) 202510224722.3

(51) Int. Cl. G01R 31/327; H03K 17/56

(52) U.S. Cl. CPC G01R 31/3277; H03K 17/56

(57) ABSTRACT

This switch circuit state detection device includes a switch, a first drive circuit, a second drive circuit, a switch input detection circuit, and a processing unit, in which the processing unit differentiates the first pulse signal from the second pulse signal, and sets a common on period in which only a portion of an on period of the first pulse signal and at least a portion of an on period of the second pulse signal overlap with each other, sets a first condition that a high period of the switch input signal when the switch is instructed to be turned on is the same as an on period obtained by subtracting the common on period of the first pulse signal and the second pulse signal from the on period of the first pulse signal, sets a second condition that the high period of the switch input signal is the same as the on period of the first pulse signal when the switch is instructed to be turned off, determines that the switch is in an on state when the first condition is satisfied, determines that the switch is in an off state when the second condition is satisfied, and determines that there is a failure in electronic components when at least one of the first condition and the second condition is not satisfied.

### CROSS-REFERENCE TO RELATED APPLICATION

The present application claims priority based on Chinese Patent Application No. 202510224722.3, filed Feb. 26, 2025, the content of which is incorporated herein by reference.

### BACKGROUND OF THE INVENTION

### Field of the Invention

The present disclosure relates to a switch circuit state detection device.

### Description of Related Art

Conventionally, there is a known method for detecting a presence or absence of a failure in electronic components based on whether input signals of switch circuits of a plurality of systems differ from each other. However, when switch contact points of the plurality of systems are included, there is a problem that a circuit configuration becomes large in size. For this reason, it is desirable to be able to accurately detect the presence or absence of a failure in electronic components even in a circuit configuration that has switch contact points of only one system.

Conventionally, for example, there is a known switch input detection circuit (see, for example, Japanese Unexamined Patent Application, First Publication No. H06-177726) that includes a connection control device provided between a reference potential point (ground) and a switch, and a potential detection device provided between a power supply and the switch. The connection control device controls a potential on a first end side of the switch in response to whether the switch is turned on or off. The potential detection device detects a potential on a second end side of the switch. This switch input detection circuit detects an on or off state of the switch based on an interruption detection signal for determining a state of the connection control device in response to each of the on and off states of the switch, and the potential of the second end side of the switch (switch input signal) detected by the potential detection device.

Conventionally, for example, electronic devices equipped with a power supply circuit and a switch state detection circuit provided between a power supply and a switch (see, for example, Japanese Unexamined Patent Application, First Publication No. 2015-201411) are known. This electronic device detects a state of the switch and a presence or absence of an abnormality in the power supply circuit by comparing a control pulse supplied to the power supply circuit to control the power supply with a switch input signal detected by the switch state detection circuit.

### SUMMARY OF THE INVENTION

However, in technology related to switch circuit state detection, it is desirable to accurately detect not only the on and off states of the switch, but also the presence or absence of a failure in various electronic components of the switch circuit. For example, the conventional switch input detection circuits or electronic devices described above only detect specific abnormalities, such as abnormal connections of the switch or sticking in power supply circuits, but are unable to adequately detect a failure in electronic components.

Aspects of the present disclosure aim to provide a switch circuit state detection device that can accurately detect a failure in electronic components.

To achieve the objective described above, a switch circuit state detection device according to an aspect of the present disclosure employs the following configuration.
(1) A first aspect of the present disclosure includes a switch, a first drive circuit which is connected between a first end of the switch and a power supply, and switches a conductive state with the power supply in response to a first pulse signal, a second drive circuit which is connected between a second end of the switch and a reference potential point, and switches a conductive state with the reference potential point in response to a second pulse signal, a switch input detection circuit which is connected between the first end of the switch and the first drive circuit, and outputs a switch input signal related to a signal input to the switch and a processing unit which supplies the first pulse signal to the first drive circuit and the second pulse signal to the second drive circuit, and receives the switch input signal from the switch input detection circuit, in which the processing unit differentiates the first pulse signal from the second pulse signal, and sets a common on period in which only a portion of an on period of the first pulse signal and at least a portion of an on period of the second pulse signal overlap with each other, sets a first condition that a high period of the switch input signal when the switch is instructed to be turned on is the same as an on period obtained by subtracting the common on period of the first pulse signal and the second pulse signal from the on period of the first pulse signal, sets a second condition that the high period of the switch input signal is the same as the on period of the first pulse signal when the switch is instructed to be turned off, determines that the switch is in an on state when the first condition is satisfied, determines that the switch is in an off state when the second condition is satisfied, and determines that there is a failure in electronic components when at least one of the first condition and the second condition is not satisfied.
(2) In the aspect of (1) described above, the switch input detection circuit may set the switch input signal to a high level for a first combination in which the switch is instructed to be turned off and the first drive circuit is in a conductive state, set the switch input signal to a high level for a second combination in which the switch is instructed to be turned on, the first drive circuit is in a conductive state, and the second drive circuit is in a non-conductive state, and set the switch input signal to a low level when a combination of on and off instruction states of the switch and conductive and non-conductive states of the first drive circuit and the second drive circuit is any combination other than the first combination and the second combination.
(3) In the aspect of (1) or (2) described above, the switch circuit state detection device may further include a monitoring circuit which is connected between the second end of the switch and an output terminal of the first drive circuit and the second drive circuit, and outputs a monitoring signal related to a conductive state of the reference potential point in response to an operation of the second drive circuit, in which the processing unit may determine, as a third condition, that a high period of the monitoring signal received from the monitoring circuit is the same as an on period obtained by subtracting a common on period of the first pulse signal and the second pulse signal from the on period of the first pulse signal, and determine that there is a failure in electronic components when at least one of the first, second, and third conditions is not satisfied.
(4) In the aspect of (3) described above, the monitoring circuit may set the monitoring signal to a high level for a third combination in which the first drive circuit is in a conductive state and the second drive circuit is in a non-conductive state, and set the monitoring signal to a low level when a combination of the conductive and non-conductive states of the first drive circuit and the second drive circuit is any combination other than the third combination.
(5) A second aspect of the present disclosure includes a switch, a first drive circuit which is connected between a first end of the switch and a power supply, and switches a conductive state with a power supply in response to a first pulse signal, a second drive circuit which is connected between a second end of the switch and a reference potential point, and switches a conductive state with the reference potential point in response to a second pulse signal, a switch input detection circuit which is connected between the second end of the switch and the second drive circuit, and outputs a switch input signal related to a signal input to the switch, and a processing unit which supplies the first pulse signal to the first drive circuit and the second pulse signal to the second drive circuit, and receives the switch input signal from the switch input detection circuit, in which the processing unit differentiates the first pulse signal from the second pulse signal, and sets a common on period in which only a portion of an on period of the second pulse signal and at least a portion of an on period of the first pulse signal overlap with each other, sets a first condition that a low period of the switch input signal when the switch is instructed to be turned on is the same as an on period obtained by subtracting the common on period of the first pulse signal and the second pulse signal from the on period of the second pulse signal, sets a second condition that the low period of the switch input signal is the same as the on period of the second pulse signal when the switch is instructed to be turned off, determines that the switch is in an on state when the first condition is satisfied, determines that the switch is in an off state when the second condition is satisfied, and determines that there is a failure in electronic components when at least one of the first condition and the second condition is not satisfied.
(6) In the aspect of (5) described above, the switch input detection circuit may set the switch input signal to a low level for a first combination in which the switch is instructed to be turned off and the second drive circuit is in a conductive state, set the switch input signal to a low level for a second combination in which the switch is instructed to be turned on, and the first drive circuit is in a non-conductive state and the second drive circuit is in a conductive state, and set the switch input signal to a high level when a combination of the on and off instruction states of the switch and the conductive state and non-conductive state of the first drive circuit and the second drive circuit is any combination other than the first combination and the second combination.
(7) In the aspect of (5) or (6) described above, the switch circuit state detection device further includes a monitoring circuit which is connected between the first end of the switch and an output terminal of the second drive circuit and the first drive circuit, and outputs a monitoring signal related to a conductive state with the power supply in response to an operation of the first drive circuit, in which the processing unit may determine, as a third condition, that a low period of the monitoring signal received from the monitoring circuit is the same as an on period obtained by subtracting the common on period of the first pulse signal and the second pulse signal from the on period of the second pulse signal, and determine that there is a failure in electronic components when at least one of the first, second, and third conditions is not satisfied.
(8) In the aspect of (7) described above, the monitoring circuit may set the monitoring signal to a low level for a third combination in which the first drive circuit is in a non-conductive state and the second drive circuit is in a conductive state, and set the monitoring signal to a high level when a combination of the conductive and non-conductive states of the first drive circuit and the second drive circuit is any combination other than the third combination.

According to the aspects of the present disclosure, by providing a processing unit that determines whether the first condition and the second condition based on the first pulse signal, the second pulse signal, the switch input signal, and the on or off state of the switch are satisfied, it is possible to accurately detect whether there is a failure in the electronic components of the switch circuit.

### BRIEF DESCRIPTION OF THE DRAWINGS

FIG. 1 is a configuration diagram of a switch circuit state detection device according to an embodiment of the present disclosure.

FIG. 2 is a circuit configuration diagram of the switch circuit state detection device according to the embodiment of the present disclosure.

FIG. 3 is a diagram which shows an example of a mutual corresponding relationship between a first pulse signal Pulse1, a second pulse signal Pulse2, a switch input signal SWin, and an on or off state of a switch in the switch circuit state detection device according to the embodiment of the present disclosure.

FIG. 4 is a configuration diagram of a switch circuit state detection device according to a first modified example of the embodiment of the present disclosure.

FIG. 5 is a circuit configuration diagram of a switch circuit state detection device according to a first modified example of the embodiment of the present disclosure.

FIG. 6 is a diagram which shows a first example of a mutual corresponding relationship between a first pulse signal Pulse1, a second pulse signal Pulse2, a switch input signal SWin, a monitoring signal PMon, and an on or off state of a switch in a switch circuit state detection device according to a first modified example of the embodiment of the present disclosure, where the first pulse signal Pulse1 and the second pulse signal Pulse2 are pulse signals with the same period but different duty ratios.

FIG. 7 is a diagram which shows a second example of the corresponding relationship between the first pulse signal Pulse1, the second pulse signal Pulse2, the switch input signal SWin, the monitoring signal PMon, and the on or off state of the switch in the switch circuit state detection device according to the first modified example of the embodiment of the present disclosure, where the first pulse signal Pulse1 and the second pulse signal Pulse2 are pulse signals with mutually different frequencies.

FIG. 8 is a diagram which shows a third example of the corresponding relationship between the first pulse signal Pulse1, the second pulse signal Pulse2, the switch input signal SWin, the monitoring signal PMon, and the on or off state of the switch in the switch circuit state detection device according to the first modified example of the embodiment of the present disclosure, where the first pulse signal Pulse1 and the second pulse signal Pulse2 are pulse signals with the same period but different phases.

FIG. 9 is a configuration diagram of a switch circuit state detection device according to a second modified example of the embodiment of the present disclosure.

FIG. 10 is a configuration diagram of the switch circuit state detection device according to the third modified example of the embodiment of the present disclosure.

FIG. 11 is a circuit configuration diagram of the switch circuit state detection device according to the third modified example of the embodiment of the present disclosure.

FIG. 12 is a diagram which shows an example of a mutual corresponding relationship between a first pulse signal Pulse1, a second pulse signal Pulse2, a switch input signal SWin, and an on or off state of a switch in the switch circuit state detection device according to the third modified example of the embodiment of the present disclosure.

FIG. 13 is a configuration diagram of a switch circuit state detection device according to a fourth modified example of the embodiment of the present disclosure.

FIG. 14 is a circuit configuration diagram of the switch circuit state detection device according to the fourth modified example of the embodiment of the present disclosure.

FIG. 15 is a diagram which shows an example of a mutual corresponding relationship between a first pulse signal Pulse1, a second pulse signal Pulse2, a switch input signal SWin, a monitoring signal PMon, and an on or off state of a switch in the switch circuit state detection device according to the fourth modified example of the embodiment of the present disclosure.

FIG. 16 is a perspective view which shows a configuration of a shift lever device equipped with any one of the switch circuit state detection devices according to the embodiment, first modified example, second modified example, third modified example and fourth modified example of the present disclosure.

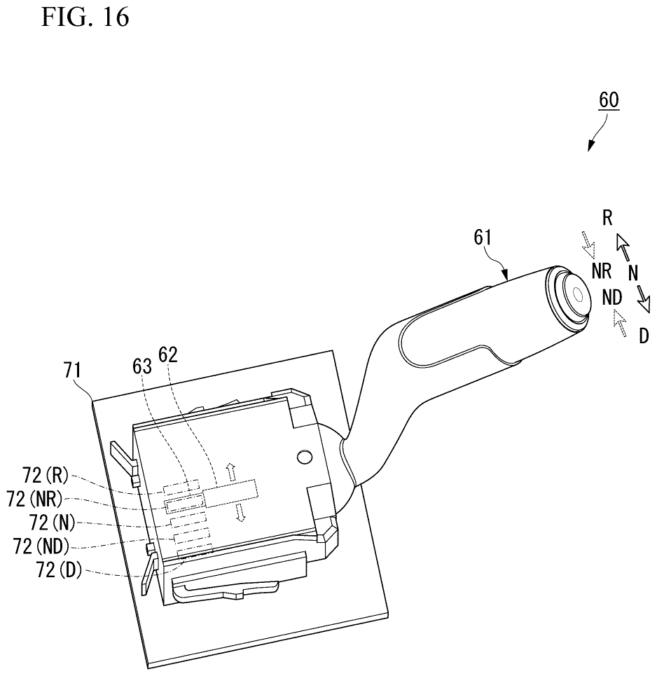

### DESCRIPTION OF EMBODIMENTS

A switch circuit state detection device according to an embodiment of the present disclosure will now be described with reference to the accompanying drawings.

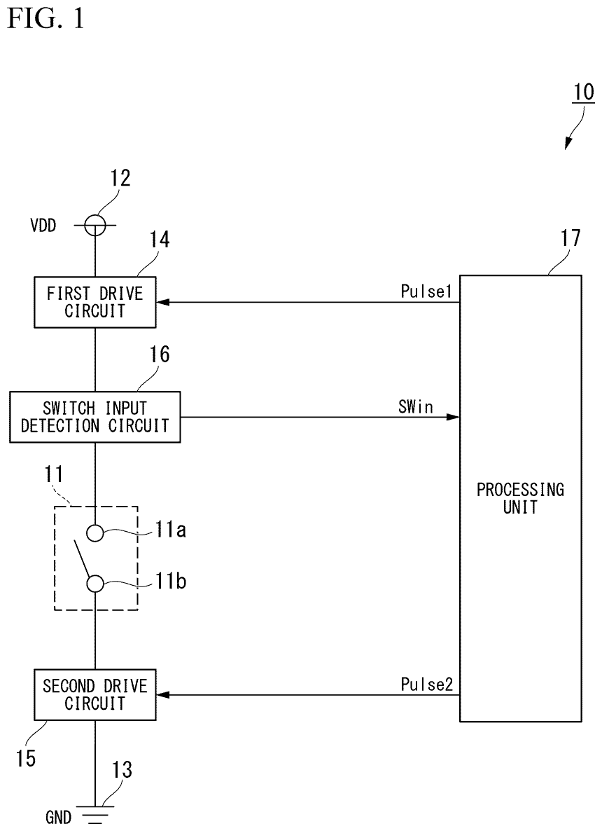

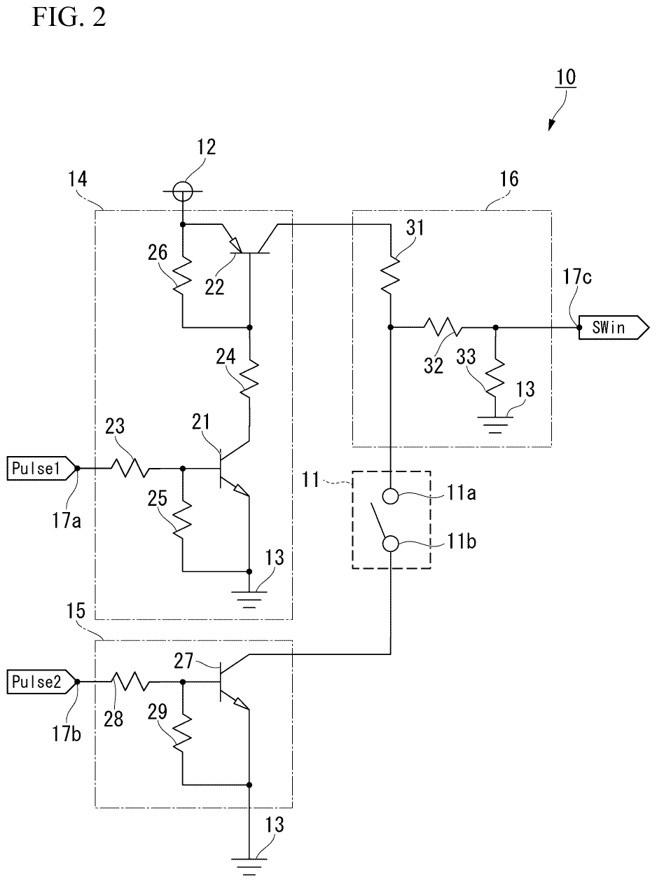

FIG. 1 is a configuration diagram of a switch circuit state detection device 10 according to an embodiment. FIG. 2 is a circuit configuration diagram of the switch circuit state detection device 10 according to the embodiment.

As shown in FIGS. 1 and 2, the switch circuit state detection device 10 according to the embodiment includes, for example, a switch 11, a power supply 12, a reference potential point 13, a first drive circuit 14, a second drive circuit 15, a switch input detection circuit 16, and a processing unit 17.

The switch 11 is, for example, a sliding contact point-type mechanical switch or the like.

The power supply 12 is, for example, a DC power supply.

The reference potential point 13 is a reference point for a predetermined reference potential, such as 0 V potential, which is obtained by grounding.

The first drive circuit 14 is connected, for example, between a first end 11a of the switch 11 and the power supply 12.

As shown in FIG. 2, the first drive circuit 14 includes, for example, a first transistor 21, a second transistor 22, a first base resistor 23, a second base resistor 24, a first base-emitter resistor 25, and a second base-emitter resistor 26.

The first transistor 21 is, for example, an NPN-type transistor. An emitter of the first transistor 21 is connected to the reference potential point 13.

The second transistor 22 is, for example, a PNP-type transistor. An emitter of the second transistor 22 is connected to the power supply 12. A collector of the second transistor 22 is connected to the first end 11a of the switch 11 via, for example, a pull-up resistor 31 which will be described below.

The first base resistor 23 is connected between a first signal output terminal 17a of a processing unit 17 and a base of the first transistor 21. The first signal output terminal 17a of the processing unit 17 is a terminal or the like that outputs a first pulse signal Pulse1 which will be described below.

The second base resistor 24 is connected to a base of the second transistor 22 and a collector of the first transistor 21.

The first base-emitter resistor 25 is connected between the base and emitter of the first transistor 21.

The second base-emitter resistor 26 is connected between the base and emitter of the second transistor 22.

The first drive circuit 14 drives the power supply 12 on the second transistor 22 side via, for example, the first transistor 21. The first transistor 21 switches between on and off states in response to the first pulse signal Pulse1 input from the first signal output terminal 17a of the processing unit 17 to the first base resistor 23. The first pulse signal Pulse1 is a voltage pulse signal that is turned on (ON) due to a predetermined high-level output voltage and turned off (OFF) due to a predetermined low-level output voltage. The second transistor 22 switches its conductive state with the power supply 12 by the first transistor 21 switching between on and off states. For example, in response to the first transistor 21 being turned on, the second transistor 22 switches from an off state to an on state as a current flows from the emitter to the first transistor 21 via the base.

The second drive circuit 15 is connected between, for example, a second end 11b of the switch 11 and the reference potential point 13.

The second drive circuit 15 includes, for example, a third transistor 27, a third base resistor 28, and a third base-emitter resistor 29.

The third transistor 27 is, for example, an NPN-type transistor. An emitter of the third transistor 27 is connected to the reference potential point 13. A collector of the third transistor 27 is connected to the second end 11b of the switch 11.

The third base resistor 28 is connected between the second signal output terminal 17b of the processing unit 17 and a base of the third transistor 27. The second signal output terminal 17b of the processing unit 17 is a terminal that outputs a second pulse signal Pulse2 which will be described below.

The third base-emitter resistor 29 is connected between the base and emitter of the third transistor 27.

The second drive circuit 15 drives the reference potential point 13 via, for example, the third transistor 27. The third transistor 27 switches its conductive state with the reference potential point 13 by switching between on and off states in response to the second pulse signal Pulse2 input from the second signal output terminal 17b of the processing unit 17 to the third base resistor 28. The second pulse signal Pulse2 is a voltage pulse signal that is turned on (ON) based on a predetermined high-level output voltage and turned off (OFF) based on a predetermined low-level output voltage.

The switch input detection circuit 16 is connected between the first end 11a of the switch 11 and the first drive circuit 14. The switch input detection circuit 16 includes, for example, a pull-up resistor 31, an input protection resistor 32, and a pull-down resistor 33.

The pull-up resistor 31 is connected between, for example, the collector of the second transistor 22 and the first end 11a of the switch 11. The pull-up resistor 31 sets a switch input signal SWin, which will be described below, to a high level (H), for example, when the switch 11 is instructed to be turned off and the first drive circuit 14 is in a conductive state.

The input protection resistor 32 is connected between a first signal input terminal 17c of the processing unit 17 and the first end 11a of the switch 11. The first signal input terminal 17c of the processing unit 17 is a terminal that receives the switch input signal SWin, which will be described below. The input protection resistor 32 protects the processing unit 17 from an input of an overvoltage caused by, for example, surge noise or the like.

The pull-down resistor 33 is connected between the first signal input terminal 17c of the processing unit 17 and the reference potential point 13. The pull-down resistor 33 prevents the switch input signal SWin from becoming an open output, for example, when a potential of neither the power supply 12 nor the reference potential point 13 is conveyed.

The switch input detection circuit 16 outputs the switch input signal SWin, which relates to a signal input to the switch 11, to the first signal input terminal 17c of the processing unit 17. The switch input signal SWin is a voltage pulse signal with high (H) and low (L) voltage levels. The high level (H) of the switch input signal SWin is a voltage greater than a predetermined minimum high-level input voltage at which the processing unit 17 can recognize a high level of an input voltage. A low level (L) of the switch input signal SWin is a voltage less than a maximum low-level input voltage at which the processing unit 17 can recognize a low level of the input voltage.

Table 1 below shows combinations of the high and low levels of the switch input signal SWin, on and off instruction states of the switch 11, conductive and non-conductive states of the first drive circuit 14, and conductive and non-conductive states of the second drive circuit 15.

As shown in Table 1 below, the switch input detection circuit 16 sets the switch input signal SWin to a high level when the switch 11 is instructed to be turned off and the first drive circuit 14 is in a conductive state (a case of a first combination). The switch input detection circuit 16 sets the switch input signal SWin to a high level when the switch 11 is instructed to be turned on, the first drive circuit 14 is in a conductive state, and the second drive circuit 15 is in a non-conductive state (a case of a second combination). The switch input detection circuit 16 sets the switch input signal SWin to a low level for any combination other than the first and second combinations described above in Table 1 below.

TABLE 1

| | First drive | Second drive | |
|---|---|---|---|
| | circuit 14 | circuit 15 | SWin |
| Switch 11 | (conductive/non- | (conductive/non- | (High/Low |
| (ON/OFF) | conductive) | conductive) | level) |
| OFF | Non-conductive | Non-conductive | Low level |
| OFF | Non-conductive | Conductive | Low level |
| OFF | Conductive | Non-conductive | High level |
| OFF | Conductive | Conductive | High level |
| ON | Non-conductive | Non-conductive | Low level |
| ON | Non-conductive | Conductive | Low level |
| ON | Conductive | Non-conductive | High level |
| ON | Conductive | Conductive | Low level |

The processing unit 17 includes a software functional unit that functions when a predetermined program is executed by a processor such as a central processing unit (CPU). The software functional unit is an electronic control unit (ECU) that includes a processor such as a CPU, a read only memory (ROM) that stores a program, a random access memory (RAM) that temporarily stores data, and electronic circuits such as a timer. Note that a part of the processing unit 17 may include an integrated circuit such as a large scale integration (LSI).

The processing unit 17 supplies a first pulse signal Pulse1 to the first drive circuit 14 and a second pulse signal Pulse2 to the second drive circuit 15, and receives a switch input signal SWin from the switch input detection circuit 16.

Hereinafter, an operation of the switch circuit state detection device 10 according to the embodiment will be described.

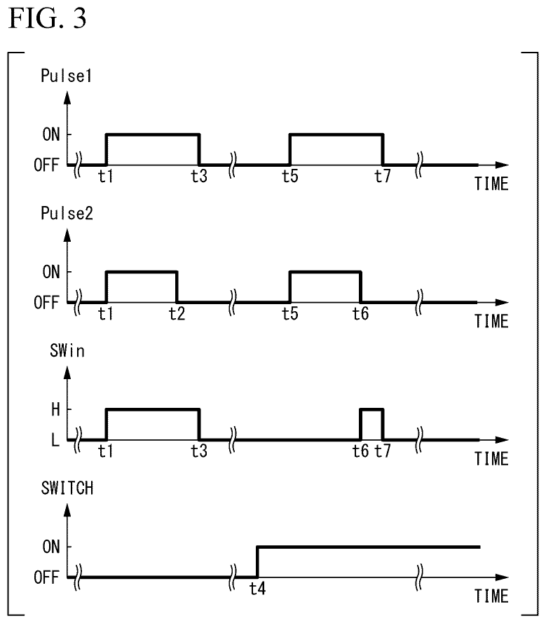

FIG. 3 shows an example of a mutual corresponding relationship between the first pulse signal Pulse1, the second pulse signal Pulse2, the switch input signal SWin, and an on or off state of the switch 11 in the switch circuit state detection device 10 according to the embodiment.

The processing unit 17 determines whether there is a failure in electronic components of the switch circuit state detection device 10 based on the first pulse signal Pulse1, the second pulse signal Pulse2, the switch input signal SWin, and the on or off state of the switch 11. Note that the failure in the electronic components of the switch circuit state detection device 10 does not include, for example, a contact point defect in the switch 11, or the like.

When it is determined whether there is a failure in the electronic components of the switch circuit state detection device 10, the processing unit 17 differentiates the first pulse signal Pulse1 from the second pulse signal Pulse2. The processing unit 17 outputs each of the first pulse signal Pulse1 and the second pulse signal Pulse2 so that they have a common on period. The common on period is an on period in which only a portion of an on period of the first pulse signal Pulse1 and at least a portion of an on period of the second pulse signal Pulse2 overlap with each other.

The processing unit 17 sets, as a first condition, that a high period of the switch input signal SWin when the switch 11 is instructed to be turned on is the same as an on period obtained by subtracting a common on period of the first pulse signal Pulse1 and the second pulse signal Pulse2 from the on period of the first pulse signal Pulse1. The processing unit 17 detects an on state of the switch 11 under the first condition.

The processing unit 17 determines, as a second condition, that the high period of the switch input signal SWin when the switch 11 is instructed to be turned off is the same as the on period of the first pulse signal Pulse1. The processing unit 17 detects the off state of the switch 11 under the second condition.

The processing unit 17 determines that there is a failure in the electronic components of the switch circuit state detection device 10 when at least one of the first and second conditions is not satisfied.

For example, the first pulse signal Pulse1 and the second pulse signal Pulse2 shown in FIG. 3 are pulse signals with the same period but different duty ratios. The common on (ON) period of the first pulse signal Pulse1 and the second pulse signal Pulse2 is a period from a time t1 to a time t2 when the switch 11 is turned off, and a period from a time t5 to a time t6 when the switch 11 is turned on (ON).

If the switch circuit state detection device 10 is normal, the high (H) period of the switch input signal SWin when the switch 11 is turned off (OFF) is the same as the on period of the first pulse signal Pulse1 (a period from the time t1 to a time t3) (first condition). The high (H) period of the switch input signal SWin when the switch 11 is turned on (ON) is the same as the on period (a period from the time t6 to a time t7) obtained by subtracting the common on period of the first pulse signal Pulse1 and the second pulse signal Pulse2 from the on period of the first pulse signal Pulse1 (second condition).

As described above, the switch circuit state detection device 10 of the embodiment includes the processing unit 17 that determines whether the first and second conditions are met, thereby accurately detecting whether there is a failure in the electronic components of the switch circuit state detection device 10.

### Modified Example

Modified examples of the embodiment are described below. Note that parts that are the same as those in the embodiment described above are denoted by the same reference numerals, and their description will be omitted or simplified.

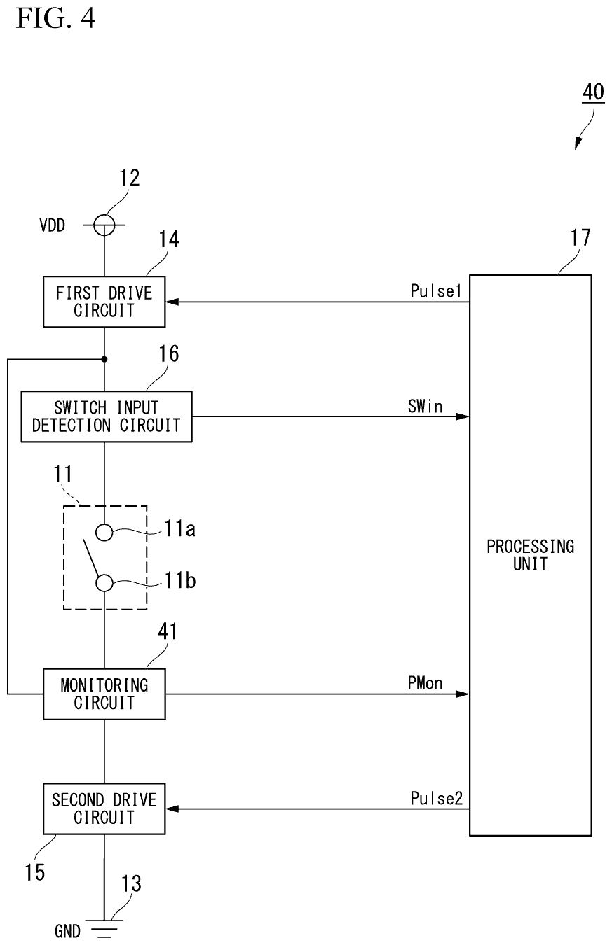

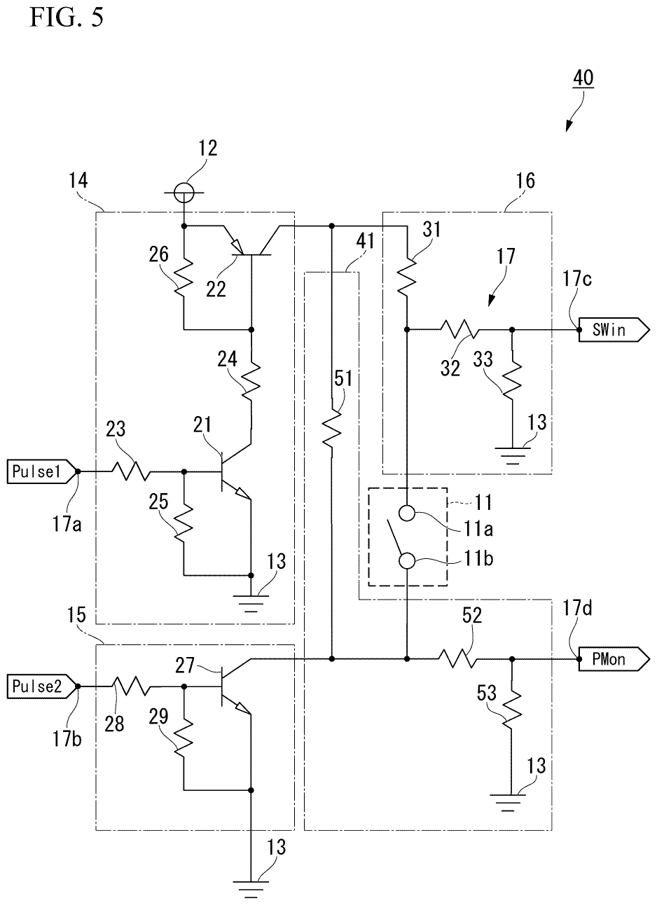

FIG. 4 is a configuration diagram of a switch circuit state detection device 40 according to a first modified example of the embodiment. FIG. 5 is a circuit diagram of a switch circuit state detection device 40 according to the first modified example of the embodiment.

As shown in FIGS. 4 and 5, the switch circuit state detection device 40 according to the first modified example of the embodiment includes, for example, a switch 11, a power supply 12, a reference potential point 13, a first drive circuit 14, a second drive circuit 15, a switch input detection circuit 16, a processing unit 17, and a monitoring circuit 41.

The monitoring circuit 41 is connected between the second end 11b of the switch 11, the collector of the second transistor 22 (that is, an output terminal of the first drive circuit 14), and the second drive circuit 15. The monitoring circuit 41 includes, for example, a pull-up resistor 51, an input protection resistor 52, and a pull-down resistor 53.

The pull-up resistor 51 is connected between the collector of the second transistor 22 and the collector of the third transistor 27. The pull-up resistor 51 sets a monitoring signal PMon, which will be described below, to a high level (H), for example, when the switch 11 is instructed to be turned off, the first drive circuit 14 is in a conductive state, and the second drive circuit 15 is in a non-conductive state.

The input protection resistor 52 is connected between a second signal input terminal 17d of the processing unit 17 and the second end 11b of the switch 11. The second signal input terminal 17d of the processing unit 17 is a terminal that receives an input of the monitoring signal PMon, which will be described below. The input protection resistor 52 protects the processing unit 17 from the input of an overvoltage caused by, for example, surge noise.

The pull-down resistor 53 is connected between the second signal input terminal 17d of the processing unit 17 and the reference potential point 13. The pull-down resistor 53 prevents the monitoring signal PMon from becoming an open output, for example, when a potential of neither the power supply 12 nor the reference potential point 13 is conveyed.

The monitoring circuit 41 outputs a monitoring signal PMon, which indicates the conductive state with the reference potential point 13 in response to an operation of the second drive circuit 15 to the second signal input terminal 17d of the processing unit 17. The monitoring signal PMon is a voltage pulse signal with high (H) and low (L) voltage levels. A high level (H) of the monitoring signal PMon is a voltage greater than the predetermined minimum high-level input voltage at which the processing unit 17 can recognize the high level of an input voltage. The low level (L) of the switch input signal SWin is a voltage less than the maximum low-level input voltage at which the processing unit 17 can recognize the low level of the input voltage.

Table 2 below shows combinations of high and low levels of the monitoring signal PMon, the conductive and non-conductive states of the first drive circuit 14, and the conductive and non-conductive states of the second drive circuit 15.

As shown in Table 2 below, when the first drive circuit 14 is in a conductive state and the second drive circuit 15 is in a non-conductive state (a case of a third combination), the monitoring circuit 41 sets the monitoring signal PMon to a high level. For any combination other than the third combination in Table 2 below, the monitoring circuit 41 sets the monitoring signal PMon to a low level.

TABLE 2

| First drive | Second drive | |
|---|---|---|
| circuit 14 | circuit 15 | PMon |
| (conductive/non- | (conductive/non- | (High/Low |
| conductive) | conductive) | level) |
| Non-conductive | Non-conductive | Low level |
| Non-conductive | Conductive | Low level |
| Conductive | Non-conductive | High level |
| Conductive | Conductive | Low level |

An operation of the switch circuit state detection device 40 according to the first modified example of the embodiment will be described below.

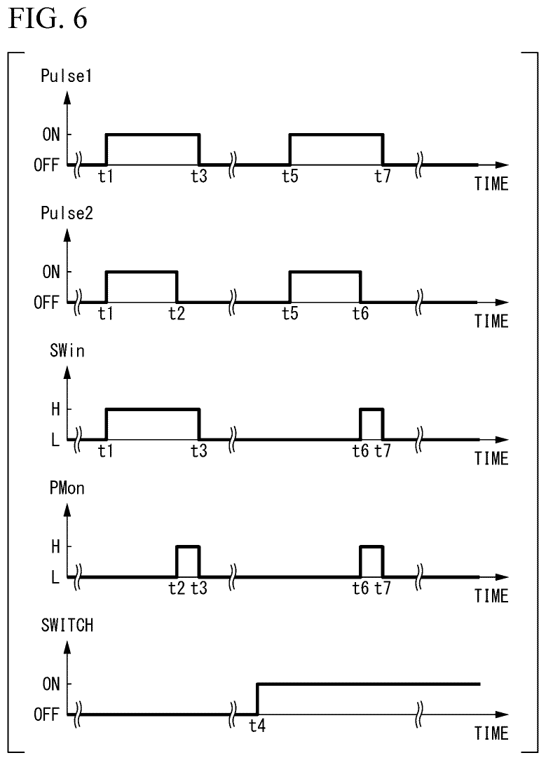

FIG. 6 is a diagram which shows a first example of the mutual corresponding relationship between the first pulse signal Pulse1, the second pulse signal Pulse2, the switch input signal SWin, the monitoring signal PMon, and the on or off state of the switch 11 in the switch circuit state detection device 40 according to the first modified example of the embodiment. FIG. 6 shows a case where the first pulse signal Pulse1 and the second pulse signal Pulse2 are pulse signals with the same period but different duty ratios.

The processing unit 17 according to the first modified example determines whether there is a failure in electronic components of the switch circuit state detection device 40 based on the first pulse signal Pulse1, the second pulse signal Pulse2, the switch input signal SWin, the monitoring signal PMon, and the on or off state of the switch 11.

When it is determined whether there is a failure in the electronic components of the switch circuit state detection device 40, the processing unit 17 according to the first modified example differentiates the first pulse signal Pulse1 from the second pulse signal Pulse2, as in the embodiment described above. The processing unit 17 outputs each of the first pulse signal Pulse1 and the second pulse signal Pulse2 so that they have a common on period. The common on period is the on period in which only a portion of the on period of the first pulse signal Pulse1 and at least a portion of the on period of the second pulse signal Pulse2 overlap with each other.

The processing unit 17 sets, as a third condition, that a high period of the monitoring signal PMon is the same as the on period obtained by subtracting the common on period of the first pulse signal Pulse1 and the second pulse signal Pulse2 from the on period of the first pulse signal Pulse1.

The processing unit 17 determines that there is a failure in the electronic components of the switch circuit state detection device 40 when at least one of the first, second, and third conditions is not satisfied.

As shown in FIG. 6, the common on (ON) period of the first pulse signal Pulse1 and the second pulse signal Pulse2 is the period from the time t1 to the time t2 when the switch 11 is turned off (OFF), and the period from the time t5 to the time t6 when the switch 11 is turned on (ON).

If the switch circuit state detection device 40 is normal, a high (H) period of the monitoring signal PMon is the same as the on period obtained by subtracting the common on period of the first pulse signal Pulse1 and the second pulse signal Pulse2 from the on period of the first pulse signal Pulse1 (a period from the time t2 to the time t3 and the period from time t6 to the time t7) (third condition).

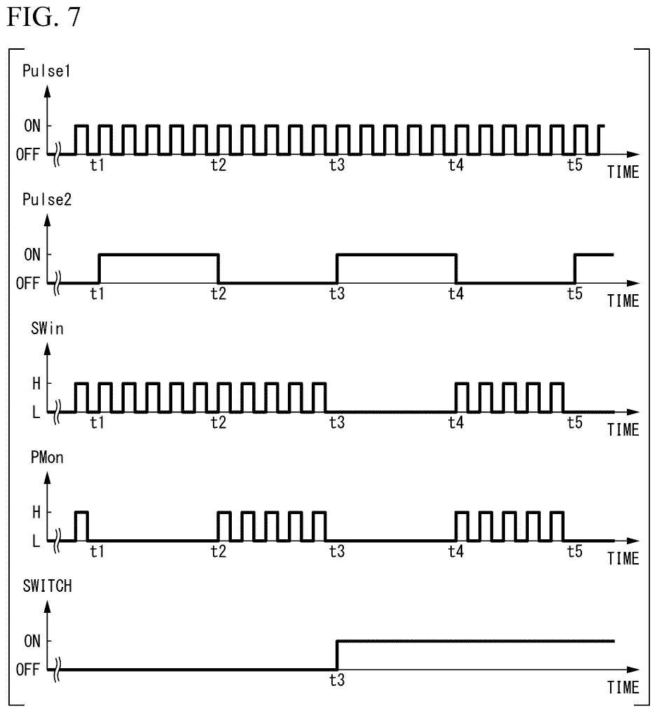

FIG. 7 is a diagram which shows a second example of the corresponding relationship between the first pulse signal Pulse1, the second pulse signal Pulse2, the switch input signal SWin, the monitoring signal PMon, and the on or off state of the switch in the switch circuit state detection device 40 according to the first modified example of the embodiment. FIG. 7 shows a case where the first pulse signal Pulse1 and the second pulse signal Pulse2 are pulse signals with different frequencies.

As shown in FIG. 7, the common on (ON) period of the first pulse signal Pulse1 and the second pulse signal Pulse2 is the on (ON) period of the first pulse signal Pulse1 in the period from the time t1 to the time t2 when the switch 11 is turned off (OFF), and the on (ON) period of the first pulse signal Pulse1 in a period from the time t3 to a time t4 when the switch 11 is turned on (ON).

If the switch circuit state detection device 40 is normal, the high (H) period of the switch input signal SWin when the switch 11 is turned off (OFF) is the same as the on period of the first pulse signal Pulse1 (first condition). The high (H) period of the switch input signal SWin when the switch 11 is turned on (ON) is the same as the on period obtained by subtracting the common on period of the first pulse signal Pulse1 and the second pulse signal Pulse2 from the on period of the first pulse signal Pulse1, that is, the on period of the first pulse signal Pulse1 in a period from the time t4 to the time t5 (second condition).

If the switch circuit state detection device 40 is normal, the high (H) period of the monitoring signal PMon is the same as the on period obtained by subtracting the common on period of the first pulse signal Pulse1 and the second pulse signal Pulse2 from the on period of the first pulse signal Pulse1, that is, the on period of the first pulse signal Pulse1 in each of the period from the time t2 to the time t3 and the period from the time t4 to the time t5 (third condition).

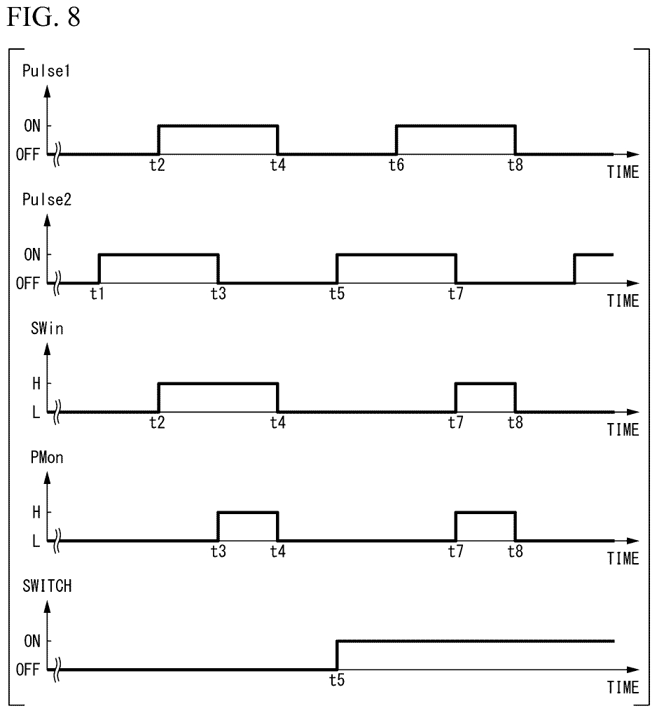

FIG. 8 is a diagram which shows a third example of the corresponding relationship between the first pulse signal Pulse1, the second pulse signal Pulse2, the switch input signal SWin, the monitoring signal PMon, and the on or off state of the switch 11 in the switch circuit state detection device 40 according to the first modified example of the embodiment. FIG. 8 shows a case where the first pulse signal Pulse1 and the second pulse signal Pulse2 are pulse signals of the same period but different phases.

As shown in FIG. 8, the common on (ON) period of the first pulse signal Pulse1 and the second pulse signal Pulse2 is the period from the time t2 to the time t3 when the switch 11 is turned off (OFF), and the period from the time t6 to the time t7 when the switch 11 is turned on (ON).

If the switch circuit state detection device 40 is normal, the high (H) period of the switch input signal SWin when the switch 11 is turned off (OFF) is the same as the on period of the first pulse signal Pulse1 (a period from the time t2 to the time t4) (first condition). The high (H) period of the switch input signal SWin when the switch 11 is turned on (ON) is the same as the on period (a period from the time t7 to a time t8) obtained by subtracting the common on period of the first pulse signal Pulse1 and the second pulse signal Pulse2 from the on period of the first pulse signal Pulse1 (second condition).

If the switch circuit state detection device 40 is normal, the high (H) period of the monitoring signal PMon is the same as the on period (the period from the time t3 to the time t4 and the period from the time t7 to the time t8) obtained by subtracting the common on period of the first pulse signal Pulse1 and the second pulse signal Pulse2 from the on period of the first pulse signal Pulse1 (third condition).

A method for detecting the first, second, and third conditions is not limited to a method for detecting the sameness of the high (H) period, including change timings of the high and low levels of each of the signals SWin and PMon. For example, it may be a method for detecting the sameness of the high (H) period per unit time, or a method for detecting the sameness of the low (L) period excluding the high (H) period.

According to the first modified example, the processing unit 17 determines whether the third condition based on the monitoring signal PMon is satisfied in addition to the first and second conditions, thereby accurately determining whether there is a failure in the electronic components of the second drive circuit 15 when the switch 11 is in the off state, or the like. Moreover, even if an electronic component in the switch input detection circuit 16 has a failure, it is possible to detect a failure in electronic components of the first drive circuit 14.

In the embodiment described above and first modified example, the switch input detection circuit 16 and the monitoring circuit 41 each include pull-down resistors 33 and 53, but the present invention is not limited to this. For example, an input circuit of the processing unit 17 may include pull-down resistors connected between each of the first signal input terminal 17c and the second signal input terminal 17d and the reference potential point 13.

In the embodiment and first modified example described above, the switch circuit state detection devices 10 and 40 are described as having a single common processing unit 17, but the present invention is not limited thereto. For example, each of the switch circuit state detection devices 10 and 40 may have a plurality of processing devices that perform different processing operations.

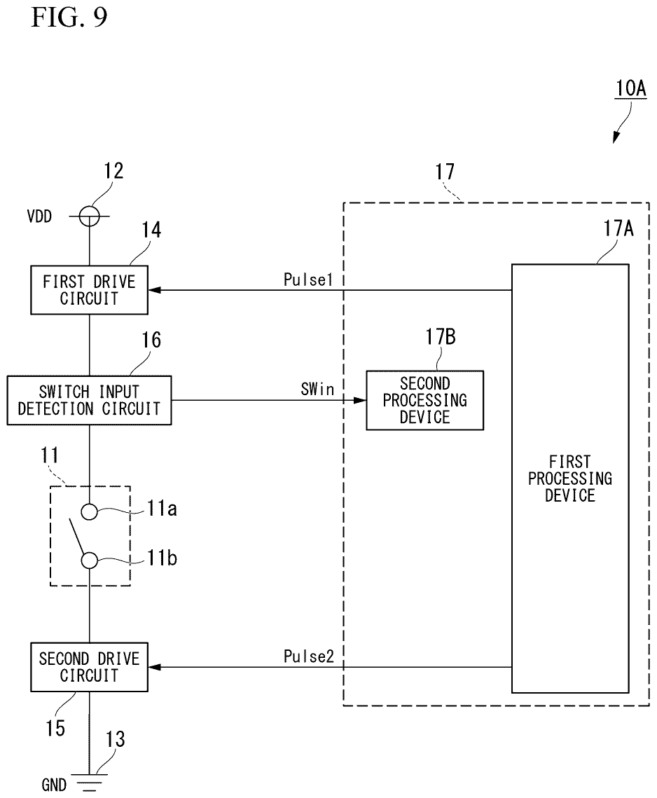

FIG. 9 is a configuration diagram of a switch circuit state detection device 10A according to a second modified example of the embodiment.

As shown in FIG. 9, the switch circuit state detection device 10A according to the second modified example includes the processing unit 17 having, for example, a first processing device 17A and a second processing device 17B. The first processing device 17A supplies the first pulse signal Pulse1 to the first drive circuit 14 and the second pulse signal Pulse2 to the second drive circuit 15. The second processing device 17B receives a switch input signal SWin from the switch input detection circuit 16.

In the switch circuit state detection device 10A according to the second modified example, a presence or absence of a failure in the electronic components may be determined by, for example, one of the first processing device 17A and the second processing device 17B, which transmit and receive information to and from each other, or by another processing device that comprehensively controls the first processing device 17A and the second processing device 17B.

Note that, for example, when the switch circuit state detection device 40 according to the first modified example described above includes the first processing device 17A and the second processing device 17B, the second processing device 17B may receive the switch input signal SWin from the switch input detection circuit 16 and the monitoring signal PMon from the monitoring circuit 41.

In the embodiment described above, the switch input detection circuit 16 is connected to the first end 11a side of the switch 11, but the present invention is not limited thereto. For example, the switch input detection circuit 16 may also be connected to the second end 11b of the switch 11.

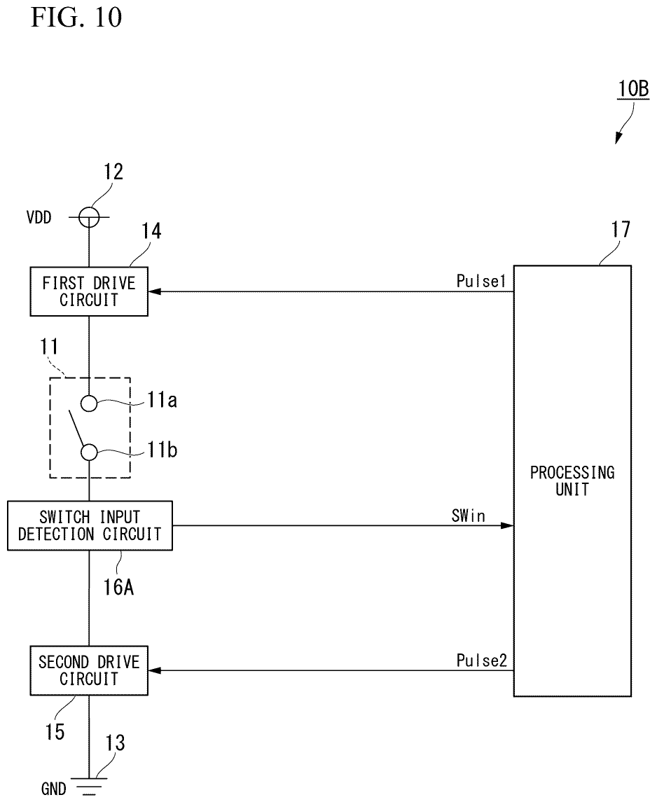

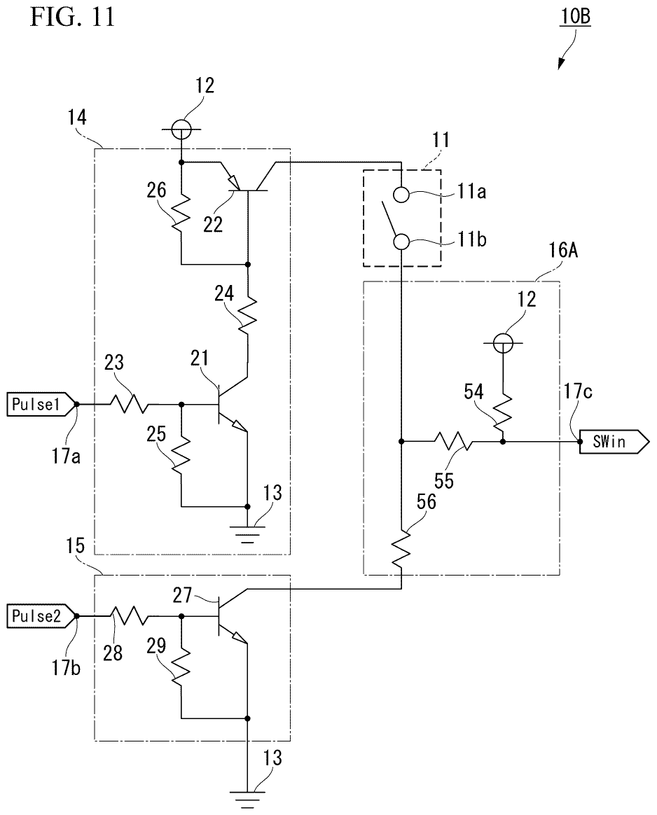

FIG. 10 is a configuration diagram of a switch circuit state detection device 10B according to a third modified example of the embodiment. FIG. 11 is a circuit configuration diagram of the switch circuit state detection device 10B according to the third modified example of the embodiment.

As shown in FIGS. 10 and 11, the switch circuit state detection device 10B according to the third modified example of the embodiment includes, for example, the switch 11, the power supply 12, the reference potential point 13, the first drive circuit 14, the second drive circuit 15, a switch input detection circuit 16A, and the processing unit 17.

The switch input detection circuit 16A is connected between the second end 11b of the switch 11, the power supply 12, and the second drive circuit 15. The switch input detection circuit 16A includes, for example, a pull-up resistor 54, an input protection resistor 55, and a pull-down resistor 56.

The pull-up resistor 54 is connected, for example, between the power supply 12 and the first signal input terminal 17c of the processing unit 17. The pull-up resistor 54 prevents the switch input signal SWin from becoming an open output, for example, when a potential of neither the power supply 12 nor the reference potential point 13 is conveyed.

The input protection resistor 55 is connected between the first signal input terminal 17c of the processing unit 17 and the second end 11b of the switch 11. The input protection resistor 55 protects the processing unit 17 from the input of an overvoltage caused by, for example, surge noise.

The pull-down resistor 56 is connected between the collector of the third transistor 27 and the second end 11b of the switch 11. The pull-down resistor 56 sets the switch input signal SWin to a low level (L), for example, when the switch 11 is instructed to be turned off and the second drive circuit 15 is in a conductive state.

The switch input detection circuit 16A of the third modified example outputs the switch input signal SWin related to a signal input to the switch 11 to the first signal input terminal 17c of the processing unit 17.

The switch input signal SWin of the third modified example is a voltage pulse signal with high (H) and low (L) voltage levels. The high level (H) of the switch input signal SWin is a voltage greater than the minimum high-level input voltage at which the processing unit 17 can recognize the high level of an input voltage. The low level (L) of the switch input signal SWin is a voltage less than the maximum low-level input voltage at which the processing unit 17 can recognize the low level of the input voltage.

Table 3 below shows combinations of the high and low levels of the switch input signal SWin, the on and off states of the switch 11, the conductive and non-conductive states of the first drive circuit 14, and the conductive and non-conductive states of the second drive circuit 15.

As shown in Table 3 below, the switch input detection circuit 16A of the third modified example sets the switch input signal SWin to a low level when the switch 11 is instructed to be turned off and the second drive circuit 15 is in the conductive state (a case of a fourth combination). The switch input detection circuit 16A sets the switch input signal SWin to a low level when the switch 11 is instructed to be turned on, the first drive circuit 14 is in the non-conductive state, and the second drive circuit 15 is in the conductive state (a case of a fifth combination). The switch input detection circuit 16A sets the switch input signal SWin to high level for any combination other than the fourth and fifth combinations described above in Table 3 below.

TABLE 3

| | First drive | Second drive | |
|---|---|---|---|
| | circuit 14 | circuit 15 | SWin |
| Switch | (conductive/non- | (conductive/non- | (High/Low |
| 11(on/off) | conductive) | conductive) | level) |
| OFF | Non-conductive | Non-conductive | High level |
| OFF | Non-conductive | Conductive | Low level |
| OFF | Conductive | Non-conductive | High level |
| OFF | Conductive | Conductive | Low level |
| ON | Non-conductive | Non-conductive | High level |
| ON | Non-conductive | Conductive | Low level |
| ON | Conductive | Non-conductive | High level |
| ON | Conductive | Conductive | High level |

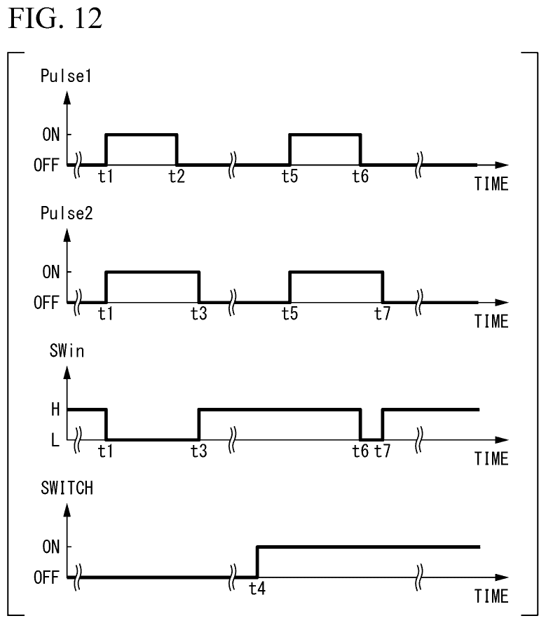

FIG. 12 is a diagram which shows an example of the mutual corresponding relationship between the first pulse signal Pulse1, the second pulse signal Pulse2, the switch input signal SWin, and the on or off state of the switch 11 in the switch circuit state detection device 10B according to a third modified example of the embodiment.

The processing unit 17 of the third modified example determines whether there is a failure in electronic components of the switch circuit state detection device 10B based on the first pulse signal Pulse1, the second pulse signal Pulse2, the switch input signal SWin, and the on or off state of the switch 11.

When it is determined whether there is a failure in the electronic components of the switch circuit state detection device 10B, the processing unit 17 differentiates the first pulse signal Pulse1 from the second pulse signal Pulse2. The processing unit 17 outputs each of the first pulse signal Pulse1 and the second pulse signal Pulse2 so that they have a common on period. The common on period is an on period in which only at least a portion of the on period of the first pulse signal Pulse1 and only a portion of the on period of the second pulse signal Pulse2 overlap with each other.

The processing unit 17 sets, as a fourth condition, that a low period of the switch input signal SWin when the switch 11 is instructed to be turned on is the same as an on period obtained by subtracting the common on period of the first pulse signal Pulse1 and the second pulse signal Pulse2 from the on period of the second pulse signal Pulse2. The processing unit 17 detects an on state of the switch 11 under the fourth condition. The processing unit 17 determines, as a fifth condition, that the low period of the switch input signal SWin is the same as the on period of the second pulse signal Pulse2 when the switch 11 is instructed to be turned off. The processing unit 17 detects the off state of the switch 11 under the fifth condition.

The processing unit 17 determines that there is a failure in the electronic components of the switch circuit state detection device 10B when at least one of the fourth and fifth conditions is not satisfied.

For example, the first pulse signal Pulse1 and the second pulse signal Pulse2 shown in FIG. 12 are pulse signals with the same period but different duty cycles. The common on (ON) period of the first pulse signal Pulse1 and the second pulse signal Pulse2 is the period from the time t1 to the time t2 when the switch 11 is turned off (OFF), and the period from the time t5 to the time t6 when switch 11 is turned on (ON).

If the switch circuit state detection device 10B is normal, a low (L) period of the switch input signal SWin when the switch 11 is turned off (OFF) is the same as the on period of the second pulse signal Pulse2 (the period from the time t1 to the time t3) (fourth condition). The low (L) period of the switch input signal SWin when the switch 11 is turned on (ON) is the same as the on period (the period from the time t6 to the time t7) obtained by subtracting the common on period of the first pulse signal Pulse1 and the second pulse signal Pulse2 from the on period of the second pulse signal Pulse2 (fifth condition).

The third modified example described above may also include a circuit corresponding to the monitoring circuit 41 of the first modified example described above.

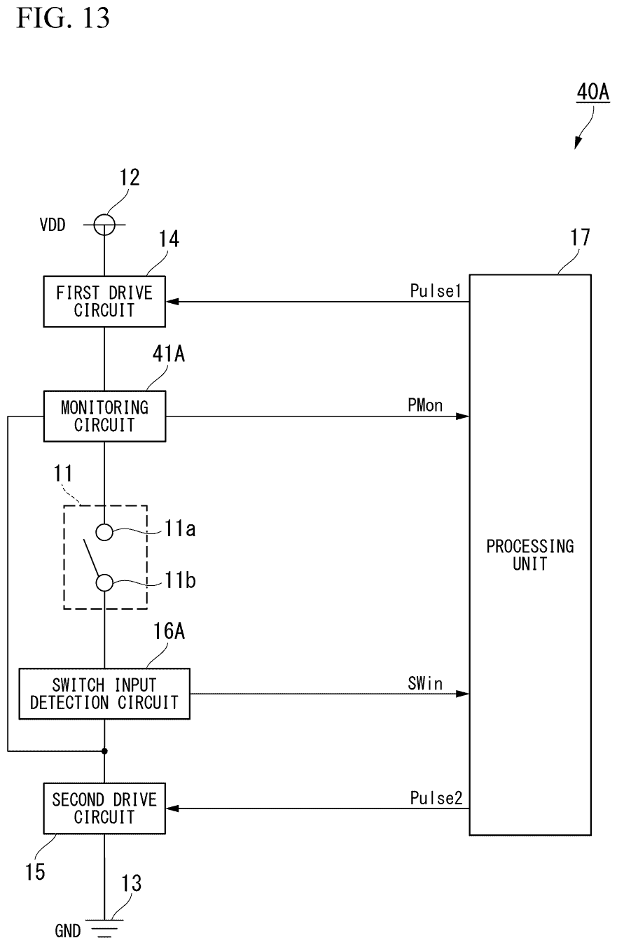

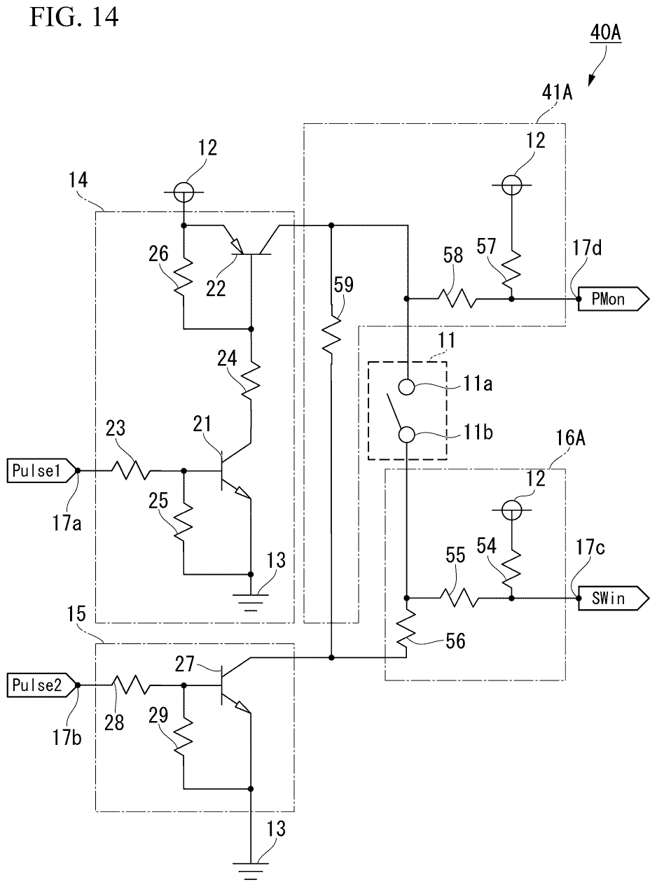

FIG. 13 is a configuration diagram of a switch circuit state detection device 40A according to a fourth modified example of the embodiment. FIG. 14 is a circuit configuration diagram of the switch circuit state detection device 40A according to the fourth modified example of the embodiment.

As shown in FIGS. 13 and 14, the switch circuit state detection device 40A according to the fourth modified example of the embodiment includes, for example, a switch 11, a power supply 12, a reference potential point 13, a first drive circuit 14, a second drive circuit 15, the switch input detection circuit 16A, the processing unit 17, and a monitoring circuit 41A.

The monitoring circuit 41A according to the fourth modified example is connected between the first end 11a of the switch 11, the collector of the third transistor 27 (that is, an output terminal of the second drive circuit 15), and the first drive circuit 14. The monitoring circuit 41A includes, for example, a pull-up resistor 57, an input protection resistor 58, and a pull-down resistor 59.

The pull-up resistor 57 is connected, for example, between the power supply 12 and the second signal input terminal 17d of the processing unit 17. The pull-up resistor 57 prevents the monitoring signal PMon from becoming an open output, for example, when a potential of neither the power supply 12 nor the reference potential point 13 is conveyed.

The input protection resistor 58 is connected between the second signal input terminal 17d of the processing unit 17 and the first end 11a of the switch 11. The input protection resistor 58 protects the processing unit 17 from the input of an overvoltage caused by, for example, surge noise.

The pull-down resistor 59 is connected between the collector of the third transistor 27 and the first end 11a of the switch 11. The pull-down resistor 59 sets the monitoring signal PMon to a low level (L), for example, when the switch 11 is instructed to be turned off, the first drive circuit 14 is in a non-conductive state, and the second drive circuit 15 is in a conductive state.

The monitoring circuit 41A of the fourth modified example outputs a monitoring signal PMon indicating the conductive state with the power supply 12 in response to the operation of the first drive circuit 14 to the second signal input terminal 17d of the processing unit 17. The monitoring signal PMon is a voltage pulse signal with high (H) and low (L) voltage levels. The high level (H) of the monitoring signal PMon is a voltage greater than the predetermined minimum high-level input voltage at which the processing unit 17 can recognize the high level of an input voltage. The low level (L) of the switch input signal SWin is a voltage less than the maximum low-level input voltage at which the processing unit 17 can recognize the low level of the input voltage.

Table 4 below shows the combinations of the high and low levels of the monitoring signal PMon, the conductive and non-conductive states of the first drive circuit 14, and the conductive and non-conductive states of the second drive circuit 15.

As shown in Table 4 below, the monitoring circuit 41A of the fourth modified example sets the monitoring signal PMon to a low level when the first drive circuit 14 is in a non-conductive state and the second drive circuit 15 is in a conductive state (a case of a sixth combination). The monitoring circuit 41A sets the monitoring signal PMon to a high level for any combination other than the sixth combination shown in Table 4 below.

TABLE 4

| First drive | Second drive | |
|---|---|---|
| circuit 14 | circuit 15 | PMon |
| (conductive/non- | (conductive/non- | (High/Low |
| conductive) | conductive) | level) |
| Non-conductive | Non-conductive | High level |
| Non-conductive | Conductive | Low level |
| Conductive | Non-conductive | High level |
| Conductive | Conductive | High level |

An operation of the switch circuit state detection device 40A according to the fourth modified example of the embodiment will be described below.

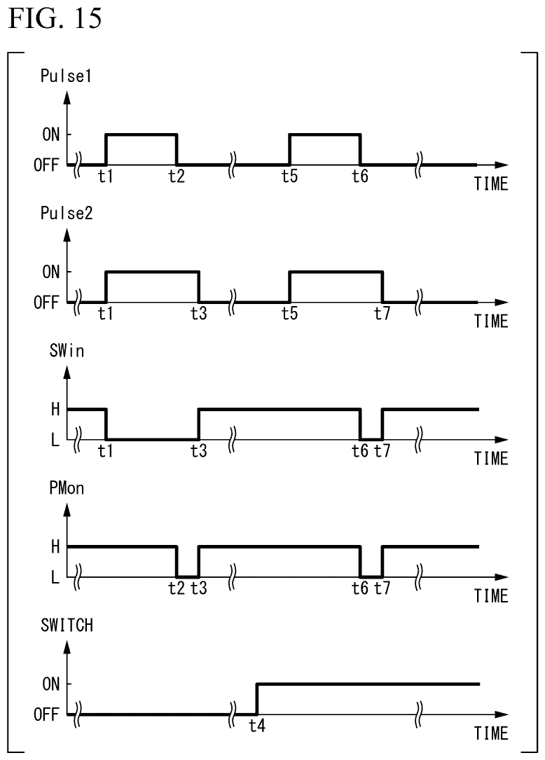

FIG. 15 is a diagram which shows an example of the mutual corresponding relationship between first pulse signal Pulse1, the second pulse signal Pulse2, the switch input signal SWin, the monitoring signal PMon, and the on or off state of the switch 11 in the switch circuit switch circuit state detection device 40A according to the fourth modified example of the embodiment. FIG. 15 shows a case where the first pulse signal Pulse1 and the second pulse signal Pulse2 are pulse signals with the same period but different duty ratios.

The processing unit 17 in the fourth modified example determines whether there is a failure in electronic components of the switch circuit state detection device 40A based on the first pulse signal Pulse1, the second pulse signal Pulse2, the switch input signal SWin, the monitoring signal PMon, and the on or off state of the switch 11.

When it is determined whether there is a failure in the electronic components of the switch circuit state detection device 40A, the processing unit 17 in the fourth modified example differentiates the first pulse signal Pulse1 from the second pulse signal Pulse2, as in the embodiment described above. The processing unit 17 outputs each of the first pulse signal Pulse1 and the second pulse signal Pulse2 so that they have a common on period. The common on period is an on period in which only at least a portion of the on period of the first pulse signal Pulse1 and only a portion of the on period of the second pulse signal Pulse2 overlap with each other.

The processing unit 17 sets, as a sixth condition, that a low period of the monitoring signal PMon is the same as an on period obtained by subtracting the common on period of the first pulse signal Pulse1 and the second pulse signal Pulse2 from the on period of the second pulse signal Pulse2.

The processing unit 17 determines that there is a failure in the electronic components of the switch circuit state detection device 40A if at least one of the fourth, fifth, and sixth conditions is not satisfied.

As shown in FIG. 15, the common on (ON) period of the first pulse signal Pulse1 and the second pulse signal Pulse2 is the period from the time t1 to the time t2 when the switch 11 is turned off (OFF), and the period from the time t5 to the time t6 when the switch 11 is turned on (ON).

If the switch circuit state detection device 40A is normal, a low (L) period of the monitoring signal PMon is the same as an on period (the period from the time t2 to the time t3 and the period from the time t6 to the time t7) obtained by subtracting the common on period of the first pulse signal Pulse1 and the second pulse signal Pulse2 from the on period of the second pulse signal Pulse1 (sixth condition).

A method for detecting the fourth, fifth, and sixth conditions is not limited to a method for detecting the sameness of the low (L) period, including change timings of the high and low levels of each of the signals SWin and PMon. For example, it may be a method for detecting the sameness of the low (L) period per unit time, or a method for detecting the sameness of the high (H) period excluding the low (L) period.

In the embodiment and modified examples described above, the switch circuit state detection devices 10, 10A, 10B, 40, and 40A each include a single switch 11. However, the present invention is not limited to this. For example, the switch circuit state detection devices 10, 10A, 10B, 40, and 40A may each include a plurality of switches 11. In this case, for example, each of the plurality of switches 11 may share each of the first drive circuit 14, the second drive circuit 15, the monitoring circuit 41, and the like.

In the embodiment and the second modified example described above, the pull-up resistor 31 is connected to the collector of the second transistor 22, but the present invention is not limited to this. For example, the pull-up resistor 31 may be connected between the power supply 12 and the emitter of the second transistor 22.

In the third modified example described above, the pull-down resistor 56 is connected to the collector of the third transistor 27, but the present invention is not limited to this. For example, the pull-down resistor 56 may be connected between the reference potential point 13 and the emitter of the third transistor 27.

FIG. 13 is a perspective view which shows a configuration of a shift lever device 60 including one of the switch circuit state detection devices 10, 10A, 10B, 40, and 40A according to the embodiment, first modified example, second modified example, third modified example, and fourth modified example.

The shift lever device 60 is mounted in, for example, a vehicle. The shift lever device 60 includes, for example, a shift lever 61, a lever holder 62, a contact holder 63, a substrate 71, and multiple contact points 72.

The shift lever 61 is, for example, a shift lever of a tilting type that is tilted in both directions in a predetermined direction, or a rotating type that is rotated around an axis. The shift lever 61 is a so-called auto-return type, and automatically returns to a predetermined reference position or posture after changing its position or posture in response to an operation of an operator from the predetermined reference position or reference posture.

The shift lever 61 switches between a plurality of states, for example, five states such as reverse (R), neutral-reverse (NR), neutral (N), neutral-drive (ND), and drive (D). Reverse (R) is selected when an instruction to travel backward is received from the operator. Neutral reverse (NR) is selected when a vehicle automatically returns to a predetermined reference position or posture after receiving an instruction to travel backward from the operator. Drive (D) is selected when an instruction to travel forward is received from the operator. Neutral drive (ND) is selected when the vehicle automatically returns to a predetermined reference position or posture after receiving an instruction to travel forward from the operator. Neutral (N) is selected when an instruction to cut off power transmission is received from the operator.

The lever holder 62 is, for example, connected to a base of the shift lever 61 and is displaced in conjunction with an operation of the shift lever 61.

The contact holder 63 holds, for example, a movable contact point and is connected to the lever holder 62 to displace the movable contact point in conjunction with the operation of the lever holder 62.

The substrate 71 includes, for example, a plurality of contact points 72, for example, five contact points 72 (R, NR, N, ND, D), arranged side by side in a predetermined direction.

Of the plurality of contact points 72, for example, five contact points 72 (R, NR, N, ND, D), one contact point 72 is conductive with the movable contact point of the contact holder 63 in response to the displacement of the lever holder 62 and the contact holder 63, which are in conjunction with the shift lever 61.

The plurality of contact points 72 and movable contact point of the shift lever device 60 constitute the switch 11 in the switch circuit state detection devices 10, 10A, 10B, 40, and 40A. For example, the five contact points 72 (R, NR, N, ND, D) correspond to five first ends 11a of the switch 11, and the movable contact point corresponds to a single second end 11b of the switch 11.

The embodiments disclosed herein are presented as an example and are not intended to limit the scope of the invention. These embodiments may be embodied in a variety of forms, and various omissions, substitutions, and modifications may be made within a range not departing from the gist of the invention. These embodiments and their modifications are intended to be included in the scope of the invention and its equivalents as described in the claims, as well as in the scope and spirit of the invention.

Aspects of the present disclosure will be, for example, as follows.

### APPENDIX 1

A switch circuit state detection device includes a switch, a first drive circuit which is connected between a first end of the switch and a power supply, and switches a conductive state with the power supply in response to a first pulse signal, a second drive circuit which is connected between a second end of the switch and a reference potential point, and switches a conductive state with the reference potential point in response to a second pulse signal, a switch input detection circuit which is connected between the first end of the switch and the first drive circuit, and outputs a switch input signal related to a signal input to the switch, and a processing unit which supplies the first pulse signal to the first drive circuit and the second pulse signal to the second drive circuit, and receives the switch input signal from the switch input detection circuit, in which the processing unit differentiates the first pulse signal from the second pulse signal, and sets a common on period in which only a portion of an on period of the first pulse signal and at least a portion of an on period of the second pulse signal overlap with each other, sets a first condition that a high period of the switch input signal when the switch is instructed to be turned on is the same as an on period obtained by subtracting the common on period of the first pulse signal and the second pulse signal from the on period of the first pulse signal, sets a second condition that the high period of the switch input signal is the same as the on period of the first pulse signal when the switch is instructed to be turned off, determines that the switch is in an on state when the first condition is satisfied, determines that the switch is in an off state when the second condition is satisfied, and determines that there is a failure in electronic components when at least one of the first condition and the second condition is not satisfied.

### APPENDIX 2

The switch circuit state detection device according to Appendix 1, in which the switch input detection circuit sets the switch input signal to a high level for a first combination in which the switch is instructed to be turned off and the first drive circuit is in a conductive state, sets the switch input signal to a high level for a second combination in which the switch is instructed to be turned on, the first drive circuit is in a conductive state, and the second drive circuit is in a non-conductive state, and sets the switch input signal to a low level when a combination of on and off instruction states of the switch and conductive and non-conductive states of the first drive circuit and the second drive circuit is any combination other than the first combination and the second combination.

### APPENDIX 3

The switch circuit state detection device according to Appendix 1 or 2 further includes a monitoring circuit which is connected between the second end of the switch and an output terminal of the first drive circuit and the second drive circuit, and outputs a monitoring signal related to a conductive state of the reference potential point in response to an operation of the second drive circuit, in which the processing unit determines, as a third condition, that a high period of the monitoring signal received from the monitoring circuit is the same as an on period obtained by subtracting a common on period of the first pulse signal and the second pulse signal from the on period of the first pulse signal, and determines that there is a failure in electronic components when at least one of the first, second, and third conditions is not satisfied.

### APPENDIX 4

The switch circuit state detection device according to Appendix 3, in which the monitoring circuit sets the monitoring signal to a high level for a third combination in which the first drive circuit is in a conductive state and the second drive circuit is in a non-conductive state, and sets the monitoring signal to a low level when a combination of the conductive and non-conductive states of the first drive circuit and the second drive circuit is any combination other than the third combination.

### APPENDIX 5

A switch circuit state detection device includes a switch, a first drive circuit which is connected between a first end of the switch and a power supply, and switches a conductive state with a power supply in response to a first pulse signal, a second drive circuit which is connected between a second end of the switch and a reference potential point, and switches a conductive state with the reference potential point in response to a second pulse signal, a switch input detection circuit which is connected between the second end of the switch and the second drive circuit, and outputs a switch input signal related to a signal input to the switch, and a processing unit which supplies the first pulse signal to the first drive circuit and the second pulse signal to the second drive circuit, and receives the switch input signal from the switch input detection circuit, in which the processing unit differentiates the first pulse signal from the second pulse signal, and sets a common on period in which only a portion of an on period of the second pulse signal and at least a portion of an on period of the first pulse signal overlap with each other, sets a first condition that a low period of the switch input signal when the switch is instructed to be turned on is the same as an on period obtained by subtracting the common on period of the first pulse signal and the second pulse signal from the on period of the second pulse signal, sets a second condition that the low period of the switch input signal is the same as the on period of the second pulse signal when the switch is instructed to be turned off, determines that the switch is in an on state when the first condition is satisfied, determines that the switch is in an off state when the second condition is satisfied, and determines that there is a failure in electronic components when at least one of the first condition and the second condition is not satisfied.

### APPENDIX 6

The switch circuit state detection device according to Appendix 5, in which the switch input detection circuit sets the switch input signal to a low level for a first combination in which the switch is instructed to be turned off and the second drive circuit is in a conductive state, sets the switch input signal to a low level for a second combination in which the switch is instructed to be turned on, and the first drive circuit is in a non-conductive state and the second drive circuit is in a conductive state, and sets the switch input signal to a high level when a combination of the on and off instruction states of the switch and the conductive state and non-conductive state of the first drive circuit and the second drive circuit is any combination other than the first combination and the second combination.

### APPENDIX 7

The switch circuit state detection device according to Appendix 5 or 6 further includes a monitoring circuit which is connected between the first end of the switch and an output terminal of the second drive circuit and the first drive circuit, and outputs a monitoring signal related to a conductive state with the power supply in response to an operation of the first drive circuit, in which the processing unit determines, as a third condition, that a low period of the monitoring signal received from the monitoring circuit is the same as an on period obtained by subtracting the common on period of the first pulse signal and the second pulse signal from the on period of the second pulse signal, and determines that there is a failure in electronic components when at least one of the first, second, and third conditions is not satisfied.

### APPENDIX 8

The switch circuit state detection device according to Appendix 7, in which the monitoring circuit sets the monitoring signal to a low level for a third combination in which the first drive circuit is in a non-conductive state and the second drive circuit is in a conductive state, and sets the monitoring signal to a high level when a combination of the conductive and non-conductive states of the first drive circuit and the second drive circuit is any combination other than the third combination.

### BRIEF DESCRIPTION OF THE REFERENCE SYMBOLS

10, 10A, 10B, 40, 40A Switch circuit state detection device
11 Switch
12 Power supply
13 Reference potential point
14 First drive circuit
15 Second drive circuit
16, 16A Switch input detection circuit
17 Processing unit
17a First signal output terminal
17b Second signal output terminal
17c First signal input terminal
17d Second signal input terminal
17A First processing device
17B Second processing device
41, 41A Monitoring circuit
60 Shift lever device

What is claimed is:

1. A switch circuit state detection device comprising:
a switch;
a first drive circuit which is connected between a first end of the switch and a power supply, and switches a conductive state with the power supply in response to a first pulse signal;
a second drive circuit which is connected between a second end of the switch and a reference potential point, and switches a conductive state with the reference potential point in response to a second pulse signal;
a switch input detection circuit which is connected between the first end of the switch and the first drive circuit, and outputs a switch input signal related to a signal input to the switch; and
a processing unit which supplies the first pulse signal to the first drive circuit and the second pulse signal to the second drive circuit, and receives the switch input signal from the switch input detection circuit,
wherein the processing unit differentiates the first pulse signal from the second pulse signal, and sets a common on period in which only a portion of an on period of the first pulse signal and at least a portion of an on period of the second pulse signal overlap with each other,
sets a first condition that a high period of the switch input signal when the switch is instructed to be turned on is the same as an on period obtained by subtracting the common on period of the first pulse signal and the second pulse signal from the on period of the first pulse signal,
sets a second condition that the high period of the switch input signal is the same as the on period of the first pulse signal when the switch is instructed to be turned off,
determines that the switch is in an on state when the first condition is satisfied,
determines that the switch is in an off state when the second condition is satisfied, and
determines that there is a failure in electronic components when at least one of the first condition and the second condition is not satisfied.

2. The switch circuit state detection device according to claim 1,
wherein the switch input detection circuit sets the switch input signal to a high level for a first combination in which the switch is instructed to be turned off and the first drive circuit is in a conductive state,
sets the switch input signal to a high level for a second combination in which the switch is instructed to be turned on, the first drive circuit is in a conductive state, and the second drive circuit is in a non-conductive state, and
sets the switch input signal to a low level when a combination of on and off instruction states of the switch and conductive and non-conductive states of the first drive circuit and the second drive circuit is any combination other than the first combination and the second combination.

3. The switch circuit state detection device according to claim 1, further comprising:
a monitoring circuit which is connected between the second end of the switch and an output terminal of the first drive circuit and the second drive circuit, and outputs a monitoring signal related to a conductive state of the reference potential point in response to an operation of the second drive circuit,
wherein the processing unit determines, as a third condition, that a high period of the monitoring signal received from the monitoring circuit is the same as an on period obtained by subtracting a common on period of the first pulse signal and the second pulse signal from the on period of the first pulse signal, and
determines that there is a failure in electronic components when at least one of the first, second, and third conditions is not satisfied.

4. The switch circuit state detection device according to claim 2, further comprising:
a monitoring circuit which is connected between the second end of the switch and an output terminal of the first drive circuit and the second drive circuit, and outputs a monitoring signal related to a conductive state of the reference potential point in response to an operation of the second drive circuit,
wherein the processing unit determines, as a third condition, that a high period of the monitoring signal received from the monitoring circuit is the same as an on period obtained by subtracting a common on period of the first pulse signal and the second pulse signal from the on period of the first pulse signal, and
determines that there is a failure in electronic components when at least one of the first, second, and third conditions is not satisfied.

5. The switch circuit state detection device according to claim 3,
wherein the monitoring circuit sets the monitoring signal to a high level for a third combination in which the first drive circuit is in a conductive state and the second drive circuit is in a non-conductive state, and
sets the monitoring signal to a low level when a combination of the conductive and non-conductive states of the first drive circuit and the second drive circuit is any combination other than the third combination.

6. The switch circuit state detection device according to claim 4,
wherein the monitoring circuit sets the monitoring signal to a high level for a third combination in which the first drive circuit is in a conductive state and the second drive circuit is in a non-conductive state, and
sets the monitoring signal to a low level when a combination of the conductive and non-conductive states of the first drive circuit and the second drive circuit is any combination other than the third combination.

7. A switch circuit state detection device comprising:
a switch;
a first drive circuit which is connected between a first end of the switch and a power supply, and switches a conductive state with the power supply in response to a first pulse signal;
a second drive circuit which is connected between a second end of the switch and a reference potential point, and switches a conductive state with the reference potential point in response to a second pulse signal;
a switch input detection circuit which is connected between the second end of the switch and the second drive circuit, and outputs a switch input signal related to a signal input to the switch; and
a processing unit which supplies the first pulse signal to the first drive circuit and the second pulse signal to the second drive circuit, and receives the switch input signal from the switch input detection circuit,
wherein the processing unit differentiates the first pulse signal from the second pulse signal, and sets a common on period in which only a portion of an on period of the second pulse signal and at least a portion of an on period of the first pulse signal overlap with each other,
sets a first condition that a low period of the switch input signal when the switch is instructed to be turned on is the same as an on period obtained by subtracting the common on period of the first pulse signal and the second pulse signal from the on period of the second pulse signal,
sets a second condition that the low period of the switch input signal is the same as the on period of the second pulse signal when the switch is instructed to be turned off,
determines that the switch is in an on state when the first condition is satisfied,
determines that the switch is in an off state when the second condition is satisfied, and
determines that there is a failure in electronic components when at least one of the first condition and the second condition is not satisfied.

8. The switch circuit state detection device according to claim 5,
wherein the switch input detection circuit sets the switch input signal to a low level for a first combination in which the switch is instructed to be turned off and the second drive circuit is in a conductive state,
sets the switch input signal to a low level for a second combination in which the switch is instructed to be turned on, and the first drive circuit is in a non-conductive state and the second drive circuit is in a conductive state, and
sets the switch input signal to a high level when a combination of the on and off instruction states of the switch and the conductive state and non-conductive state of the first drive circuit and the second drive circuit is any combination other than the first combination and the second combination.

9. The switch circuit state detection device according to claim 7, further comprising:
a monitoring circuit which is connected between the first end of the switch and an output terminal of the second drive circuit and the first drive circuit, and outputs a monitoring signal related to a conductive state with the power supply in response to an operation of the first drive circuit,
wherein the processing unit determines, as a third condition, that a low period of the monitoring signal received from the monitoring circuit is the same as an on period obtained by subtracting the common on period of the first pulse signal and the second pulse signal from the on period of the second pulse signal, and
determines that there is a failure in electronic components when at least one of the first, second, and third conditions is not satisfied.

10. The switch circuit state detection device according to claim 8, further comprising:
a monitoring circuit which is connected between the first end of the switch and an output terminal of the second drive circuit and the first drive circuit, and outputs a monitoring signal related to a conductive state with the power supply in response to an operation of the first drive circuit,
wherein the processing unit determines, as a third condition, that a low period of the monitoring signal received from the monitoring circuit is the same as an on period obtained by subtracting the common on period of the first pulse signal and the second pulse signal from the on period of the second pulse signal, and
determines that there is a failure in electronic components when at least one of the first, second, and third conditions is not satisfied.

11. The switch circuit state detection device according to claim 9,
wherein the monitoring circuit sets the monitoring signal to a low level for a third combination in which the first drive circuit is in a non-conductive state and the second drive circuit is in a conductive state, and
sets the monitoring signal to a high level when a combination of the conductive and non-conductive states of the first drive circuit and the second drive circuit is any combination other than the third combination.

12. The switch circuit state detection device according to claim 10,
wherein the monitoring circuit sets the monitoring signal to a low level for a third combination in which the first drive circuit is in a non-conductive state and the second drive circuit is in a conductive state, and
sets the monitoring signal to a high level when a combination of the conductive and non-conductive states of the first drive circuit and the second drive circuit is any combination other than the third combination.
